(19) United States
(12) Patent Application Publication
(10) Pub. No.: US 2004/0217452 A1
(43) Pub. Date: Nov. 4, 2004

(54) Semiconductor chip arrangement and a method for its production

(76) Inventor: Reidar Lindstedt, Muenchen (DE)

Correspondence Address: SLATER & MATSIL, L.L.P., 17950 PRESTON RD, SUITE 1000, DALLAS, TX, 75252-5793, US

(21) Appl. No.: 10/788,805

(22) Filed: Feb. 27, 2004

(30) Foreign Application Priority Data
Feb. 28, 2003 (DE) 103 08 926.8

(51) Int. Cl. H01L 23/495

(52) U.S. Cl. 257/666

(57) ABSTRACT

The present invention relates to a semiconductor chip arrangement in which signals are interchanged between semiconductor substrates via contact areas in the side surfaces of the semiconductor substrates rather than via a mount element. The contact areas may be used as horizontally connecting contacts between semiconductor substrates which are located alongside one another, or else as vertically connecting contacts between semiconductor substrates which lie one on top of the other, thus saving connecting lines, running on the mount element, between the semiconductor substrates.

### TECHNICAL FIELD

The present invention relates generally to semiconductor devices and, more particularly, the preferred embodiment relates to a semiconductor chip arrangement and to a method for its production.

### BACKGROUND

In conventional semiconductor chips, the contacts via which signals are interchanged between different chips are fitted to the upper face of the chip, on which the electronic circuits are also arranged. Depending on the package type that is used, these contacts are soldered to mating contacts in a board by means of a suitable intermediate layer (for example an interposer or an intermediate board). The signals are transmitted between two or more semiconductor chips via interconnects on the board.

The concept of transmitting signals via board interconnects that has been used until now results in the problem that signals always have to be transmitted via a number of contact points, specifically from the chip to the board interconnect and from the board interconnect to the chip, and over long distances. Furthermore, if the interconnect density is high, expensive multilayer boards are required, whose price rises with each additional interconnect layer.

These problems are impeding the process of continuously speeding up signal transmission while reducing the relative signal amplitudes, that is, the voltage values, and continuously reducing the size of the overall electronic systems.

U.S. Pat. No. 6,014,313 describes a three-dimensional semiconductor chip arrangement in which horizontal electrical connections between adjacent chips in different chip stacks are provided via connecting elements, which are arranged above the adjacent chips. An electrical contact between the respective chips and these connecting elements is, however, once again produced via surface contacts, as is also described in more detail in U.S. Pat. No. 5,963,689.

### SUMMARY OF THE INVENTION

A preferred embodiment of the present invention provides an improved semiconductor chip arrangement comprising a mount element and at least two semiconductor chips, in which signals can be interchanged between the semiconductor chips in a simple and particularly efficient manner.

The preferred embodiment is achieved by a semiconductor chip arrangement having a mount element and at least one first and one second semiconductor substrate. Each of the two semiconductor substrates has at least one interconnect and at least one contact area that is electrically connected to the interconnect and is arranged in a side surface of the respective semiconductor substrate. The second semiconductor substrate is arranged on the first semiconductor substrate, and the first semiconductor substrate is arranged on the mount element, such that a first main surface (which runs at right angles to one side surface of the second semiconductor substrate) of the second semiconductor substrate rests on the first semiconductor substrate, and a first main surface (which runs at right angles to one side surface of the first semiconductor substrate) of the first semiconductor substrate rests on the mount element. An electrical contact is produced between the contact areas on the first and on the second semiconductor substrate.

In one aspect, the present invention provides for the electrical signals to be transmitted not only via the conventional contacts on the chip upper face but also via lateral contact areas that are arranged on the side chip surfaces. The lateral contact areas may in this case be in the form of horizontally and/or vertically connected contacts, which extend in the side chip surface as far as the chip lower face. Horizontal contacts are formed between chips, which are located alongside one another on the board, while vertically connected contacts connect chips which are located one above the other.

The lateral contact areas may be designed such that the contacts are fitted outside the chip by integrating them, for example, in a kerf, which does not contain any chip components at all but only, for example, test structures. This kerf is normally removed when the wafer is subdivided; however, if it contains the lateral contact areas, then the wafers must be subdivided such that a small portion of the lateral contact areas in each case initially remains. After the separation step, the rest of the kerf can be removed, for example, by back-etching, so that the lateral contact areas project freely.

Alternatively, the lateral contact areas may also be incorporated in the side chip surfaces, in the same way as the conventional surface contacts. This may require an additional isolation layer, which surrounds the chip at the sides, in order to prevent a short circuit to the bulk silicon or to the other contacts. If the semiconductor chips are arranged closely alongside one another on the board such that not only are the lateral contact areas electrically connected to one another but also the respective bulk silicon, undesirable interactions could occur if different potentials are applied as bias voltages to different types of chip. It is therefore necessary to additionally isolate the side chip surfaces from one another.

According to embodiments of the invention, vertically and horizontally connecting contacts may be combined by designing the contact areas on the side chip surface such that they extend as far as the chip lower face. This makes it possible to make contact simultaneously not only with laterally adjacent chips but also with chips located underneath. This is advantageous on the one hand because a contact which provides both a vertical and a horizontal connection can be produced at low cost and easily in only one method step. On the other hand, this allows chips to be arranged on top of one another and alongside one another in a particularly space-saving manner. This leads to reduced costs since, for example, it is possible to use cheaper boards with few interconnects.

In a corresponding manner, the semiconductor chips may be arranged in a very small space, for example in stacks or clusters. Compact three-dimensional chip arrangements can be produced in which electrical signals are interchanged via contact areas within the chip side surface.

According to the present invention, the lateral contact areas which are exposed in the chip side surface may also be provided combined with conventional vertical contacts that, for example, are located in the edge area but are not exposed on the chip side surface.

Aspects of the present invention may be applied to any desired semiconductor chips that, for example, each have the same electronic components or semiconductor circuits, or else different electronic components or semiconductor circuits from one another. In particular, the invention may be applied to boards with DRAM modules such as SDRAMs (synchronous dynamic random access memory) or to memory modules such as SO-DIMMs (small outline—dual in-line memory module). The present invention is suitable for components with packages, for example of the CSP type (“chip size package”), in which the processed silicon chip is fitted directly to a board, without a package.

Embodiments of the present invention can also be applied to semiconductor chips which contain only interconnects and no electronic circuits, that is, those that are used exclusively for connection of adjacent chips.

The semiconductor chip arrangement according to the preferred embodiments of the present invention allows efficient signal transmission at high speed. In this case, considerably shorter signal paths occur, with correspondingly reduced losses due to noise, and parasitic disturbance elements such as resistors. There is no need for circuitous routes via long interconnects on a board and additional contact resistances. Connecting lines are saved within a board, that is, a mount element for semiconductor substrates. This reduces the costs for designing and laying out the boards, and possibly also reduces the number of board layers. The board sizes may be reduced since adjacent chips can be fitted directly alongside one another without any space between them.

Since there is no longer any need for circuitous routes via board lines, the signal path lengths are reduced. Lower signal amplitudes may be used in a corresponding manner. This effect is particularly advantageous for horizontal connections between stacks composed of two or more semiconductor chips arranged one on top of the other, when the signals may not be transmitted via long vertical via contacts. The parasitic effects resulting from board lines, contact resistances, etc. are reduced. In particular, there is also no need for impedance matching between the interconnect on the board and the interconnects in the respective chips. This means that higher frequencies and lower amplitudes can be used for signal transmission.

The semiconductor chips may be fixed on the board using considerably lower-cost adhesive bonding methods. The thermal budget is not increased by the adhesive bonding process.

In some aspects, the present invention opens up new opportunities for fitting contacts to chips with a large number of contacts. In the case of graphics DRAMs with 64 data outputs or processor chips, the space on the surface is frequently no longer sufficient for all of the contacts. Since lateral contact areas on the side surfaces are used, more contacts can be accommodated on each chip or it is possible to reduce the chip area without having to reduce the number of contacts.

The embodiments of the present invention also allows contact to be made with lower metallization layers which are not connected by means of via contacts to the chip surface. This is a major advantage of lateral contact areas in comparison to conventional contacts on the chip upper face, which all have to be passed to the uppermost metallization layer through via contacts.

Provision is preferably made for the semiconductor substrates each to have an integrated circuit in the area of a first main surface, with this integrated circuit being connected to the interconnect on the respective semiconductor substrate. There may be one or more layers of circuits in the area of a first main surface of each semiconductor substrate, at least one of which layers of circuits is connected to the interconnect which is connected to the contact area.

Provision is preferably made for a conductive material to be applied to the contact areas in the side surfaces of the semiconductor substrates. The conductive material may be an adhesive, a solder material, a bonding material or some other material which is suitable for conductive connections.

Provision is preferably made for the lower face of the first semiconductor substrate to be attached to the mount element. The first semiconductor substrate may be fixed on the mount element by means of an adhesive or via electrical contacts, for example by means of soldered joints, or may be attached to the mount element by means of mechanical joints.

Provision is preferably made for the contact areas on the first and on the second semiconductor substrate each to extend from a first main surface to a second main surface of the respective semiconductor substrate. Provision is likewise preferably made for the contact area on the third semiconductor substrate to extend as far as a first main surface on the third semiconductor substrate. Furthermore, the contact area on the third semiconductor substrate may likewise extend as far as a second main surface on the second semiconductor substrate. The contact areas (which extend as far as the main surfaces) in the side surfaces may also make direct contact with adjacent semiconductor substrates which are adjacent to the main surfaces, via the contact areas which are arranged on the sides. Semiconductor substrates can thus be arranged adjacent to one another, and can be electrically connected to one another, in all three spatial directions.

Provision is preferably made for a dynamic random access memory to be formed on each of the semiconductor substrates. The semiconductor substrates may likewise have different types of circuits.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1A shows a conventional semiconductor chip arrangement;

FIG. 1B shows two semiconductor substrates with lateral contact areas and a mount element before assembly;

FIG. 1C shows a semiconductor chip arrangement with two semiconductor substrates and with the mount element, according to a first embodiment of the invention;

FIGS. 2A to 2C show a semiconductor chip arrangement with two semiconductor substrates and the mount element, according to a second embodiment of the invention; and

FIGS. 3A and 3B show a semiconductor chip arrangement with two semiconductor substrates and the mount element, according to a third embodiment of the invention.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

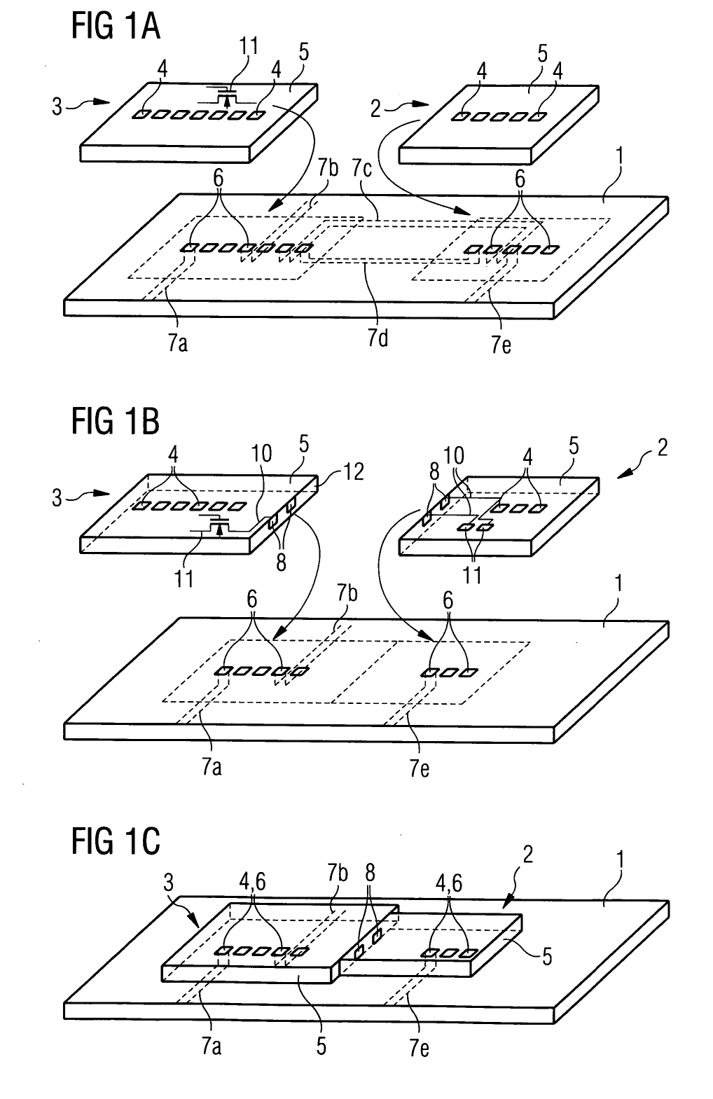

FIG. 1A shows a conventional semiconductor chip arrangement. The reference symbol 1 in FIG. 1A denotes a mount element or board, the reference symbol 2 denotes a first semiconductor substrate or chip, and the reference symbol 3 denotes a second semiconductor substrate or chip. Both the electronic circuits 11 and the electrical upper face contacts 4 are arranged on the upper faces 5 of the semiconductor substrates 2 and 3. The semiconductor substrates 2 and 3 are arranged on the mount element 1 such that the upper faces 5 of the substrates 2 and 3 rest on the mount element 1, and an electrical contact is produced between the upper face contacts 4 of the substrates 2 and 3 and the contacts 6 on the mount element 1.

Signals are transmitted between the chips 2, 3 via interconnects 7a, 7b, 7c, 7d and 7e which are embedded in the board 1. Single-layer or multilayer boards are used, depending on the density of the interconnects. The greater the number of layers that are required, the more expensive the boards are, and hence also the overall electronic system.

The reference symbol 2 in FIG. 1B denotes a first chip which, in the area of its upper face 5, has one or more electronic circuits 11 or components, in particular integrated circuits such as DRAM memory cells for example, surface contacts 4 and, in its side surface 12, lateral contact areas 8. Interconnects 10 which produce an electrical connection between the lateral contacts 8 and the electronic circuits 11 are likewise provided. The reference symbol 3 denotes a second chip, which likewise has two or more electronic circuits and surface contacts 4 in the area of its upper face 5, and lateral contact areas 8 in its side surface 12. The reference symbol 1 denotes a board with electrical contacts 6 and interconnects 7a, 7b, and 7e.

The electronic circuits or components of both chips 2 and 3 have been produced in a conventional manner. In addition, however, the chips also have electrical contact areas 8 in their side surface. These lateral contacts may in this case be produced in any desired manner.

According to a first exemplary embodiment of the present invention, as is shown in FIG. 1C, the two chips 2 and 3 are fitted to the board 1 such that the chip upper faces 5 in each case rest on the board surface, and the side surfaces 12 of the two chips 2 and 3 touch one another in such a way that the lateral contact areas 8, which are arranged in the side surfaces, are connected to one another. The electrical contact may in this case be reinforced by application of a conductive adhesive or of a conductive paste. However, these are applied only locally, in order to prevent a short-circuit between the lateral contact and lateral contacts at a different point of a chip, or the bulk silicon. It is also possible to improve the electrical contact by means of conductive intermediate elements arranged between the chips.

In this case, the upper face contacts 4 of the chips 2, 3 are also electrically connected to the electrical contacts 6 on the board, for example by means of suitable soldering methods. These conventional vertical contacts are required to transmit the signals to remote chips. The soldering also fixes the chips on the board. If the interconnects on the semiconductor chip are electrically connected exclusively via lateral contacts, then the semiconductor chip can be fixed on the board using lower-cost adhesive bonding methods.

Accurate lateral positioning of the chips in the same order of magnitude as the lateral extent of the contacts is necessary in order to connect the lateral contact areas 8 of the chips 2 and 3 to one another. This can be achieved with present-day automatic machines, whose positioning accuracy is in the region of micrometers or less, since the lateral extent of the contacts is approximately 100 μm.

As is shown in FIG. 1C, the two chips 2, 3 are located directly alongside one another on the board. Two lateral contact areas 8 are formed in each case, and are connected by means of a locally applied conductive adhesive, a conductive paste, a solder material or bonding material, or by means of some other conductive material, and via which the chips interchange electrical signals with one another. This saves two interconnects 7c and 7d in the board, thus making it possible to reduce the overall size of the board.

If required, the arrangement may be packaged once the semiconductor chips have been fitted to the board. For example, the entire arrangement can be encapsulated in a plastic material, for example.

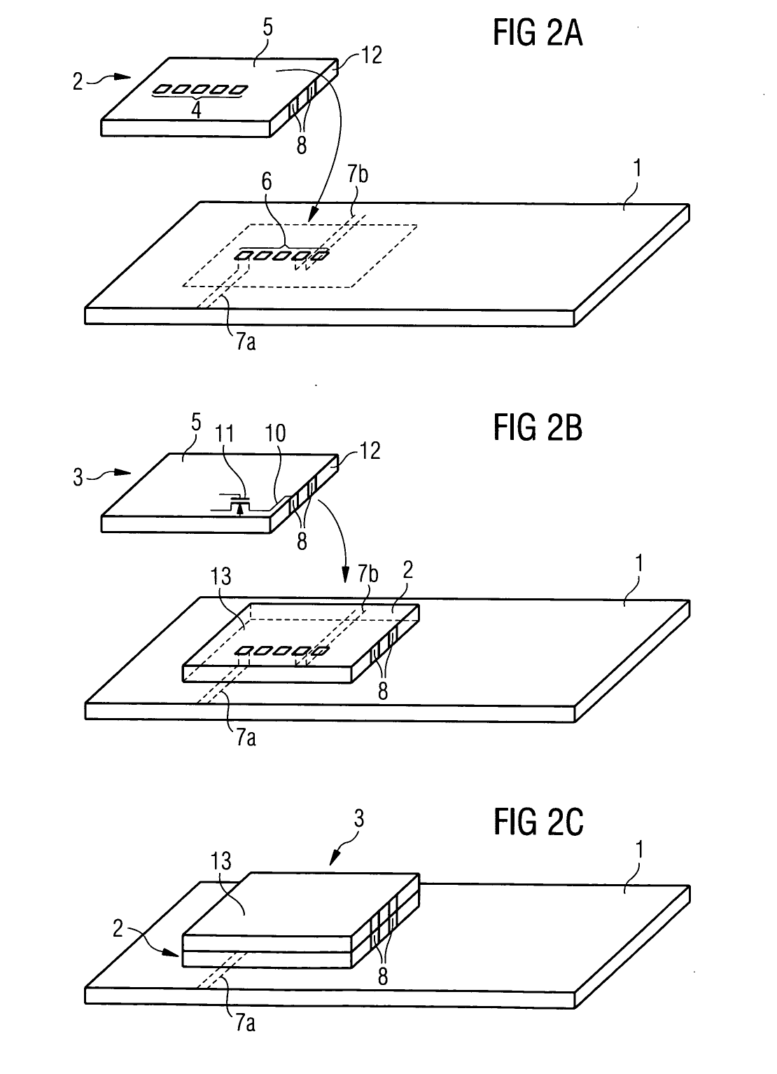

According to a second embodiment of the present invention, as is illustrated in FIGS. 2A to 2C, two semiconductor chips 2, 3 are arranged one above the other on a board 1 and are connected to one another via vertically connecting lateral contact areas 8. The two semiconductor chips 2 and 3 are designed in the same way as the semiconductor chips in the first embodiment, and the same reference symbols in each case denote the same components. However, according to this embodiment, the lateral contact areas 8 in the chip side surface 12 are designed such that they extend as far as the chip lower face 13 and as far as the chip upper face 5.

First of all, as is shown in FIG. 2A, the upper face 5 of the first semiconductor chip 2 is fitted, facing downwards, onto the board 1, so that its upper face contacts 4 are electrically connected to the board contacts 6, and are fixed using known methods. The lower face of the chip now faces upwards. Then, as is illustrated in FIG. 2B, the second semiconductor chip 3 is now fitted to the lower face of the first semiconductor chip 2 such that its upper face rests on the lower face of the first semiconductor chip 2. It is arranged in such a way that its lateral contact areas 8 make contact with the lateral contact areas 8 on the first semiconductor chip 2. If required, this electrical contact is reinforced by local application, for example, of a conductive adhesive or a conductive paste. The resultant structure is shown in FIG. 2C.

The lateral contact areas 8 may now be connected to board contacts on the side of the board 1, to the lateral contact areas on a third semiconductor chip, or to interconnects 10 in the interior of the first semiconductor chip 2. In this case as well, the components may be packaged once they have been assembled.

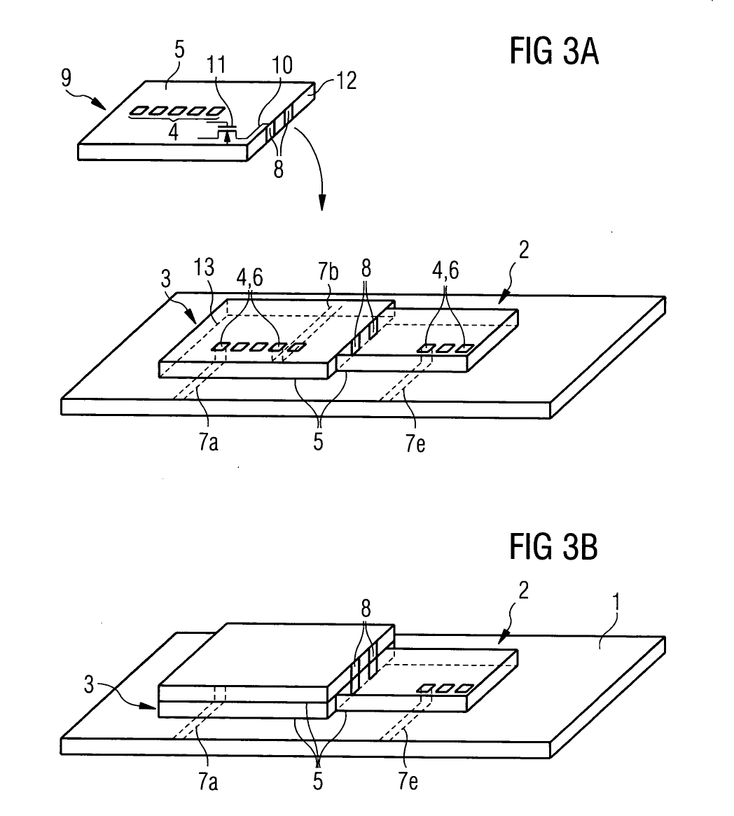

According to a third embodiment of the present invention, two semiconductor chips 2, 3 are first of all arranged alongside one another on a board 1 such that their lateral contact areas are connected to one another, as is shown in FIG. 3A. In this case as well, the design of the semiconductor chips which are used corresponds to that of the preceding embodiments, and the arrangement which is shown in FIG. 3A corresponds to the arrangement as shown in FIG. 1B according to the first embodiment of the invention. However, the lateral contact area 8 on the second semiconductor chip 3 extends within its side surface 12 as far as its lower face 13 and its upper face 5.

In a next step, a third semiconductor chip 9 is fitted to the second semiconductor chip 3 such that its upper face rests on the rear face of the semiconductor chip 3, and its lateral contact areas 8 are connected to the lateral vertical contacts on the second semiconductor chip, if required after local application of a conductive adhesive or a conductive paste. The third semiconductor chip 9 is designed in a similar way to the first and the second. Its lateral contact areas 8 may extend as far as its lower face 13, depending on the future purpose, for example if additional chips are intended to be fitted and to be connected via lateral and vertical contacts.

This results in the structure shown in FIG. 3B.

In a corresponding manner, two or more layers of identical or different semiconductor chips can be stacked one on top of the other and alongside one another, and can be electrically connected to one another by means of the contact areas which are arranged on the chip side walls.

Furthermore, mutually adjacent semiconductor substrates can be fixed on the mount element by pressing them against one another, so that mechanical pressure produces the electrical connection between the semiconductor substrates and their contact areas.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A semiconductor chip arrangement comprising:
a mount element;
a first semiconductor substrate including at least one interconnect formed on the first semiconductor substrate and also including at least one contact area that is electrically connected to the interconnect and is arranged on a side surface of the first semiconductor substrate; and
a second semiconductor substrate having at least one interconnect formed on the second semiconductor substrate and also including at least one contact area that is electrically connected to the interconnect and is arranged on a side surface of the second semiconductor substrate;
wherein the second semiconductor substrate is arranged on the first semiconductor substrate and the first semiconductor substrate is arranged on the mount element such that a first main surface of the second semiconductor substrate rests on the first semiconductor substrate, and a first main surface of the first semiconductor substrate rests on the mount element, and wherein an electrical contact is produced between the contact area on the first semiconductor substrate and the contact area on the second semiconductor substrate.

2. The semiconductor chip arrangement of claim 1 wherein the first and second semiconductor substrates each have an integrated circuit disposed in the area of the first main surface, wherein the integrated circuit is electrically coupled to the interconnect.

3. The semiconductor chip arrangement of claim 1 and further comprising a conductive material applied between the contact area on the first semiconductor substrate and the contact area on the second semiconductor substrate.

4. The semiconductor chip arrangement of claim 1 wherein the first main surface of the first semiconductor substrate is attached to the mount element.

5. The semiconductor chip arrangement of claim 1 wherein the contact area on the first semiconductor substrate and the contact area on the second semiconductor substrate each extend from the first main surface to a second main surface of the respective semiconductor substrate.

6. The semiconductor chip arrangement of claim 1 wherein each of the first and second semiconductor substrates includes a dynamic random access memory formed therein.

7. A semiconductor chip arrangement comprising:
a mount element;
a first semiconductor substrate arranged over the mount element, the first semiconductor substrate including at least one interconnect formed thereon, the first semiconductor substrate further including at least one contact area that is electrically connected to the interconnect and is arranged along a side surface of the first semiconductor substrate;
a second semiconductor substrate arranged over the mount element alongside the first semiconductor substrate, the second semiconductor substrate including at least one interconnect formed thereon, the second semiconductor substrate further including at least one contact area that is electrically connected to the interconnect and is arranged along a side surface of the second semiconductor substrate, the second semiconductor substrate arranged so that an electrical contact is produced between the contact area of the first semiconductor substrate and the contact area of the second semiconductor substrate; and
a third semiconductor substrate arranged over the second semiconductor substrate, the third semiconductor substrate including at least one interconnect formed thereon, the third semiconductor substrate further including at least one contact area that is electrically connected to the interconnect and is arranged along a side surface of the third semiconductor substrate, the third semiconductor substrate arranged so that an electrical contact is produced between the contact area of the third semiconductor substrate and the contact area of the second semiconductor substrate.

8. The semiconductor chip arrangement of claim 7 wherein the first, second and third semiconductor substrates each have an integrated circuit disposed therein, wherein the integrated circuit is electrically coupled to the interconnect.

9. The semiconductor chip arrangement of claim 7 and further comprising a conductive material applied between the contact area on the first semiconductor substrate and the contact area on the second semiconductor substrate.

10. The semiconductor chip arrangement of claim 7 wherein the first semiconductor substrate is attached to the mount element and wherein the second semiconductor substrate is attached to the mount element.

11. The semiconductor chip arrangement of claim 7 wherein the contact areas on the first and the second semiconductor substrates each extend from a first main surface to a second main surface of the respective semiconductor substrate.

12. The semiconductor chip arrangement of claim 11 wherein the contact area on the third semiconductor substrate extends to a first main surface on the third semiconductor substrate.

13. The semiconductor chip arrangement of claim 7 wherein each of the first, second, and third semiconductor substrates includes a dynamic random access memory formed therein.

14. A method for producing a semiconductor chip arrangement, the method comprising:
providing a mount element;
providing at least a first and a second semiconductor substrate, each of the first and the second semiconductor substrates having at least one interconnect and at least one contact area that is electrically connected to the respective interconnect, the contact area being arranged in a side surface of the respective semiconductor substrate;
placing the first semiconductor substrate on the mount element so that a first main surface of the first semiconductor substrate rests on the mount element; and
placing the second semiconductor substrate on the first semiconductor substrate such that a first main surface of the second semiconductor substrate rests on a second main surface of the first semiconductor substrate and an electrical contact is produced between the contact area of the first semiconductor substrate and the contact area of the second semiconductor substrate.

15. The method of claim 14 and further comprising, before placing either the first or the second semiconductor substrate, applying a conductive material locally to the contact areas of the first and the second semiconductor substrates.

16. The method of claim 14 and further comprising encapsulating the first and second semiconductor substrates.

17. A method for producing a semiconductor chip arrangement, the method comprising:
providing a mount element;
providing a first semiconductor substrate that includes at least one interconnect formed thereon and also includes at least one contact area that is electrically connected to the interconnect and is arranged along a side surface of the first semiconductor substrate;
providing a second semiconductor substrate that includes at least one interconnect formed thereon and also includes at least one contact area that is electrically connected to the interconnect and is arranged along a side surface of the second semiconductor substrate;
providing a third semiconductor substrate that includes at least one interconnect formed thereon and also includes at least one contact area that is electrically connected to the interconnect and is arranged along a side surface of the third semiconductor substrate;
placing the first semiconductor substrate over the mount element such that a first main surface lies adjacent to the mount element;
placing the second semiconductor substrate over the mount element alongside the first semiconductor substrate such that a first main surface of the second semiconductor substrate lies adjacent to the mount element and such that an electrical contact is produced between the contact area of the first semiconductor substrate and the contact area of the second semiconductor substrate; and
placing the third semiconductor substrate over the second semiconductor substrate such that a first main surface of the third semiconductor substrate rests over a second main surface of the second semiconductor substrate, and such that an electrical contact is produced between the contact areas of the third semiconductor substrate and the contact area of the second semiconductor substrate.

18. The method of claim 17 wherein, before placing the semiconductor substrates, applying a conductive material to the contact areas of the first, second, and third semiconductor substrates.

19. The method of claim 17 and further comprising encapsulating the first, second, and third semiconductor substrates.
